(19) United States
(12) Patent Application Publication
(10) Pub. No.: US 2016/0326403 A1
(43) Pub. Date: Nov. 10, 2016

(54) Composite Sheet For Protective-Film Formation

(71) Applicant: LINTEC CORPORATION, Tokyo (JP)

(72) Inventors: Hiroyuki Yoneyama, Nagareyama-shi (JP); Naoya Saiki, Koshigaya-shi (JP); Akio Kabuto, Warabi-shi (JP)

(21) Appl. No.: 15/109,803

(22) PCT Filed: Dec. 25, 2014
(86) PCT No.: PCT/JP2014/084226

§ 371 Date: Jul. 5, 2016

(30) Foreign Application Priority Data
Jan. 8, 2014 (JP) 2014-001848

(51) Int. Cl. C09J 7/02; B32B 7/12; B32B 27/32; H01L 21/683

(52) U.S. Cl. CPC C09J 7/0217; H01L 21/6836; B32B 7/12; B32B 27/32; C09J 2423/006; C09J 2203/326; C09J 2433/00; C09J 2463/00; H01L 2221/68327; H01L 2221/68377; B32B 2307/51; B32B 2323/10

(57) ABSTRACT

A composite sheet 1 for forming a protective film which includes: a pressure sensitive adhesive sheet 2 obtained by laminating a pressure sensitive adhesive layer 22 on one surface of a base material 21; a protective film-forming film 3 laminated on the pressure sensitive adhesive layer 22 side of the pressure sensitive adhesive sheet 2; and a pressure sensitive adhesive layer 4 for jigs, the layer being laminated on a peripheral portion on the opposite side of the pressure sensitive adhesive sheet 2 side of the protective film-forming film 3, wherein a thickness of the pressure sensitive adhesive layer 22 of the pressure sensitive adhesive sheet 2 is from 1 to 8 μm.

According to the composite sheet 1 for forming a protective film, it is possible to effectively suppress loosening of the sheet 1 in the heating step and the cooling step, and the dicing and picking up processes can also be performed satisfactorily.

### TECHNICAL FIELD

The present invention relates to a composite sheet for forming a protective film (protective film-forming composite sheet) which is adhered to a workpiece such as a semiconductor wafer so that the workpiece can be subjected to processing (for example, dicing) in that state, and which is capable of forming a protective film for the workpiece or a product obtained by processing the workpiece (for example, a semiconductor chip).

### BACKGROUND ART

In recent years, a semiconductor device has been manufactured by a mounting method called a face-down method. In this method, at the time of mounting a semiconductor chip having a circuit surface on which electrodes such as bumps have been formed, the circuit surface side of the semiconductor chip is bonded to a chip mounting portion such as a lead frame. Therefore, a structure is obtained in which the back surface side of the semiconductor chip where no circuit has been formed is exposed.

For this reason, in order to protect the semiconductor chip, a protective film constituted of a hard organic material is often formed on the back surface side of the semiconductor chip. Accordingly, Patent Document 1 discloses a sheet for protective film formation and dicing that has a thermosetting, protective film forming layer capable of forming the protective film described above. According to this sheet for protective film formation and dicing, both the dicing of a semiconductor wafer and the protective film formation on the semiconductor chip can be performed, and it is possible to obtain a semiconductor chip with a protective film.

When using the above sheet for protective film formation and dicing, the peripheral edge portion of the sheet is adhered to a ring frame, while the protective film forming layer is adhered onto a semiconductor wafer, and the resultant is subjected to a heating step and a cooling step in that state. By going through these processes, the protective film forming layer is thermally cured to form a protective film.

However, if a conventional sheet for protective film formation and dicing was used, a problem has arisen in some cases in that when the sheet for protective film formation and dicing was subjected to the heating step described above while being supported by a ring frame, the sheet for protective film formation and dicing was loosened by the weight of the semiconductor wafer, and was not restored to the original state even after the cooling step. When the sheet for protective film formation and dicing was loosened in this manner, inconvenience may be caused when stored in a cassette during transport; vacuum suction on the sheets on the outer side than the wafer corresponding portion of the suction table may not be successfully carried out to cause defects such as the wrinkles in the sheet; or inconvenience may be caused when performing expansion because sheets have already been stretched.

In addition, the sheet for protective film formation and dicing disclosed in Patent Document 1 has a configuration in which the protective film forming layer is laminated directly on a support film (FIG. 1), or a configuration in which a pressure sensitive adhesive layer dedicated to the ring frame is absent (FIG. 2). If a pressure sensitive adhesive layer is absent between the support film and the protective film forming layer as in the former configuration, a problem arises in some cases in that the adhesive force between the support film and the protective film forming layer may become excessive which makes it impossible to pick up the chip, or, on the contrary, the adhesive force between the support film and the protective film forming layer may become too weak which makes the chip to fall off during dicing. Further, if a pressure sensitive adhesive layer dedicated to the ring frame is absent as in the latter configuration, the adhesive force with respect to the ring frame cannot be satisfactorily exhibited, or the picking up of the chip may become difficult.

Patent Document 2 also discloses a dicing sheet with a protective film forming layer that has the same configuration as the sheet for protective film formation and dicing of Patent Document 1. Therefore, also in the dicing sheet with a protective film forming layer, there has been a problem in some cases regarding the adhesive force as described above. Meanwhile, although Patent Document 2 has described the loosening during thermal curing, restoration in the cooling step has not been taken into consideration.

Incidentally, Patent Document 3 has disclosed a method for manufacturing a semiconductor device in which a film for the semiconductor back surface as a protective film forming layer and a dicing tape were used separately. In the method described in Patent Document 3, since the film for the semiconductor back surface is subjected to dicing in an uncured state, and the film for the semiconductor back surface is subjected to thermal curing after picking up the chip, the problems caused by loosening as mentioned above do not occur.

### CITATION LIST

### Patent Documents

[Patent Document 1] Japanese Unexamined Patent Application, First Publication No. 2010-199541

[Patent Document 2] PCT International Publication No. WO 2013/047674

[Patent Document 3] Japanese Unexamined Patent Application, First Publication No. 2012-156377

### SUMMARY OF INVENTION

### Technical Problem

The present invention has been made in view of the circumstances as described above, and has an object of providing a composite sheet for forming a protective film that is capable of effectively suppressing the loosening of the sheet in the heating and cooling steps, and also satisfactorily performing the dicing and picking up.

### Solution to Problem

In order to achieve the above object, the present invention firstly provides a composite sheet for forming a protective film, including a pressure sensitive adhesive sheet obtained by laminating a pressure sensitive adhesive layer on one surface side of a base material, a protective film-forming film laminated on the aforementioned pressure sensitive adhesive layer side of the aforementioned pressure sensitive adhesive sheet, and a pressure sensitive adhesive layer for jigs which is laminated on a peripheral edge portion on the opposite side of the aforementioned pressure sensitive adhesive sheet side of the aforementioned protective film-forming film, the composite sheet for forming a protective film characterized in that the thickness of the aforementioned pressure sensitive adhesive layer of the aforementioned pressure sensitive adhesive sheet is from 1 to 8 μm (Invention 1).

The present invention secondly provides a composite sheet for forming a protective film, including a pressure sensitive adhesive sheet obtained by laminating a pressure sensitive adhesive layer on one surface side of a base material, a protective film-forming film laminated at the central portion on the aforementioned pressure sensitive adhesive layer side of the aforementioned pressure sensitive adhesive sheet, and a pressure sensitive adhesive layer for jigs which is laminated on a peripheral edge portion on the aforementioned pressure sensitive adhesive layer side of the aforementioned pressure sensitive adhesive sheet, the composite sheet for forming a protective film characterized in that the thickness of the aforementioned pressure sensitive adhesive layer of the aforementioned pressure sensitive adhesive sheet is from 1 to 8 μm (Invention 2).

In the above inventions (Inventions 1 and 2), it is possible to satisfactorily perform the dicing and pickup by the presence of the pressure sensitive adhesive layer described above. In addition, since the thickness of the pressure sensitive adhesive layer is specified as described above, the amount of the flow of the pressure sensitive adhesive layer during heating is small, and loosening of the composite sheet for forming a protective film is suppressed. As a result, it is possible to suppress incomplete restoration of the composite sheet for forming a protective film due to the shrinkage during cooling. This makes it possible to reduce the possibility of causing troubles in subsequent steps.

In the above inventions (Inventions 1 and 2), the aforementioned base material is preferably a polypropylene film, or a laminated film of a combination of a polypropylene film and another type of film (Invention 3).

In the above inventions (Inventions 1 to 3), the aforementioned pressure sensitive adhesive layer for jigs is preferably formed so as to have a circular shape, and so that, when the aforementioned protective film-forming film is adhered to a workpiece, the gap in the plane direction between the main outer peripheral edge of the aforementioned workpiece and the inner peripheral edge of the aforementioned pressure sensitive adhesive layer for jigs is less than 10 mm (Invention 4).

In the above inventions (Inventions 1 to 4), the storage elastic modulus at 130° C. of a pressure sensitive adhesive constituting the aforementioned pressure sensitive adhesive layer is preferably from 1.0×10⁵ to 8.0×10⁶ Pa (Invention 5).

In the above inventions (Inventions 1 to 5), it is preferable that the aforementioned workpiece is a semiconductor wafer, and the aforementioned protective film-forming film is a layer for forming a protective film on the aforementioned semiconductor wafer or a semiconductor chip obtained by dicing the aforementioned semiconductor wafer (Invention 6).

### Advantageous Effects of Invention

By using the composite sheet for forming a protective film according to the present invention, the loosening of the sheet in the heating step and the cooling step can be effectively suppressed, and the dicing and picking up processes can also be performed satisfactorily.

### BRIEF DESCRIPTION OF DRAWINGS

FIG. 1 is a cross sectional view of a composite sheet for forming a protective film according to an embodiment of the present invention.

FIG. 2 is a plan view of a composite sheet for forming a protective film in a state of being adhered to a workpiece.

FIG. 3 is a cross sectional view showing an example of the use of the composite sheet for forming a protective film according to an embodiment of the present invention.

FIG. 4 is a cross sectional view of a composite sheet for forming a protective film according to another embodiment of the present invention.

FIG. 5 is a cross sectional view showing an example of the use of the composite sheet for forming a protective film according to another embodiment of the present invention.

### DESCRIPTION OF EMBODIMENTS

Embodiments of the present invention will be described below.

### First Embodiment

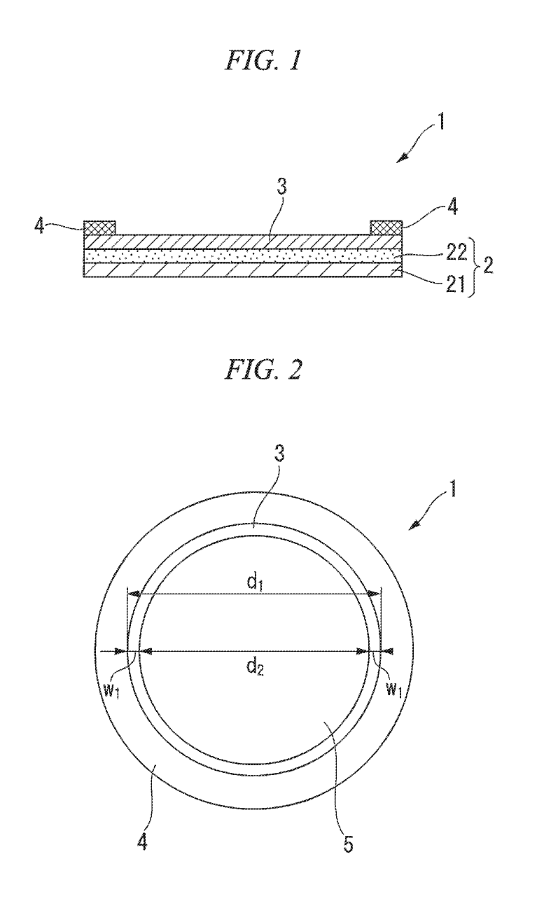

FIG. 1 is a cross sectional view of a composite sheet for forming a protective film according to an embodiment of the present invention, and FIG. 2 is a plan view of a composite sheet for forming a protective film in a state of being adhered to a workpiece. As shown in FIG. 1, a composite sheet 1 for forming a protective film (protective film-forming composite sheet) according to the present embodiment is configured by including a pressure sensitive adhesive sheet 2 obtained by laminating a pressure sensitive adhesive layer 22 on one surface of a base material 21; a protective film-forming film 3 laminated on the pressure sensitive adhesive layer 22 side of the pressure sensitive adhesive sheet 2; and a pressure sensitive adhesive layer 4 for jigs (pressure sensitive adhesive layer), the layer being laminated on a peripheral portion on the opposite side of the pressure sensitive adhesive sheet 2 side of the protective film-forming film 3. It should be noted that the protective film-forming composite sheet 1 according to the present embodiment refers to those in which the protective film-forming film 3 has not yet been adhered to the workpiece.

In the present embodiment, as shown in FIGS. 1 and 2, the base material 21 and the pressure sensitive adhesive layer 22 of the pressure sensitive adhesive sheet 2 and the protective film-forming film 3 are formed into the same size and shape, which is a circular shape in plan view, although the present invention is not limited thereto. For example, the pressure sensitive adhesive sheet 2 and the protective film-forming film 3 may have different sizes or shapes, or both may have a polygonal shape in plan view or a shape formed of a combination of an arc and a straight line, or the like.

In addition, in the present embodiment, as shown in FIGS. 1 and 2, the pressure sensitive adhesive layer 4 for jigs is formed into a circular shape, and the outer peripheral edge thereof is in the same position in plan view as an outer peripheral edge of the pressure sensitive adhesive sheet 2 and the protective film-forming film 3, although the present invention is not limited thereto. For example, the pressure sensitive adhesive layer 4 for jigs may not have a circular shape and may be truncated halfway, or the outer peripheral edge thereof may be in a different position in plan view from the outer peripheral edge of the pressure sensitive adhesive sheet 2 or the protective film-forming film 3.

The protective film-forming composite sheet 1 according to the present embodiment is used, when processing a workpiece, in order to hold the workpiece by being adhered to the workpiece, as well as to form a protective film on the workpiece or a chip obtained from the workpiece. In the present embodiment, the protective film is formed by thermally curing the protective film-forming film 3. The protective film-forming composite sheet 1 according to the present embodiment is used, as an example, in order to hold a semiconductor wafer serving as a workpiece during the dicing step of the semiconductor wafer, as well as to form a protective film on a semiconductor chip obtained by the dicing, although the present invention is not limited thereto.

### 1. Pressure Sensitive Adhesive Sheet

The pressure sensitive adhesive sheet 2 of the protective film-forming composite sheet 1 according to the present embodiment is configured to include the base material 21 and the pressure sensitive adhesive layer 22 laminated on one surface of the base material 21. Because of the presence of the pressure sensitive adhesive layer 22, by controlling the adhesive force of the pressure sensitive adhesive layer 22, the protective film-forming film 3 can be firmly fixed during dicing, and it is also possible to exert moderate releasability to an extent which is enough to easily pick up the chip obtained by dicing. If the pressure sensitive adhesive layer 22 is absent, a problem arises in some cases in that the adhesive force between the base material 21 and the protective film-forming film 3 becomes excessive which makes it impossible to pick up the chip, or, on the contrary, the adhesive force between the base material 21 and the protective film-forming film 3 becomes too weak which makes the chip to fall off during dicing.

### 1-1. Pressure Sensitive Adhesive Layer

The thickness of the pressure sensitive adhesive layer 22 in the present embodiment is from 1 to 8 μm, preferably from 2 to 8 μm, and particularly preferably from 3 to 7 μm. The material (pressure sensitive adhesive) constituting the pressure sensitive adhesive layer 22 usually has a property to exhibit fluidity at high temperatures. Although the protective film-forming composite sheet 1 which has been adhered to a workpiece and a jig such as a ring frame is applied with a load due to the weight of the workpiece, when subjected to a heating step for the thermal curing of the protective film-forming film 3 in that state, the pressure sensitive adhesive layer 22 is allowed to flow by the above-mentioned load. If the thickness of the pressure sensitive adhesive layer 22 is thick as in the conventional cases, more specifically, more than 8 μm, the flow amount of the pressure sensitive adhesive layer 22 becomes large to generate misalignment between the protective film-forming film 3 to be thermally cured and the pressure sensitive adhesive layer 22, and the loosening of the protective film-forming composite sheet 1 becomes remarkable. As a result, restoration due to shrinkage may become incomplete in the cooling step after the heating step. However, by making the thickness of the pressure sensitive adhesive layer 22 to be equal to or less than 8 μm as described above, the flow amount of the pressure sensitive adhesive layer 22 at the time of heating becomes small, and the loosening of the protective film-forming composite sheet 1 can be suppressed. As a result, it is possible to suppress incomplete restoration of the protective film-forming composite sheet 1 due to the shrinkage at the time of cooling, and the possibility of causing troubles in subsequent steps can be reduced.

On the other hand, as a result of the thickness of the pressure sensitive adhesive layer 22 being equal to or greater than 1 μm, the uniformity of the thickness by the coating can be maintained, and an appropriate level of adhesive force as the purpose of the protective film-forming composite sheet 1 can be exhibited.

The pressure sensitive adhesive layer 22 may be composed of a single layer, or may be composed of a multilayer consisted of two or more layers. In the case of a multilayer, it may be made of the same material (pressure sensitive adhesive), or may be made from different materials (pressure sensitive adhesives).

The pressure sensitive adhesive constituting the pressure sensitive adhesive layer 22 may be a non-curable pressure sensitive adhesive, or may be a curable pressure sensitive adhesive. In addition, the curable pressure sensitive adhesive may be in a state before curing, or may be in a state after curing. When the pressure sensitive adhesive layer 22 is composed of a multilayer, it may be a combination of a non-curable pressure sensitive adhesive and a curable pressure sensitive adhesive. As the non-curable pressure sensitive adhesive, for example, acrylic pressure sensitive adhesives, rubber-based pressure sensitive adhesives, silicone-based pressure sensitive adhesives, urethane-based pressure sensitive adhesives, polyester-based pressure sensitive adhesives, polyvinyl ether-based pressure sensitive adhesives, or the like can be used, and among them, acrylic pressure sensitive adhesives are preferred. As the curable pressure sensitive adhesive, for example, energy ray-curable pressure sensitive adhesives, thermosetting pressure sensitive adhesives, or the like can be used. Among them, energy ray-curable pressure sensitive adhesives are preferred, and acrylic-based, energy ray-curable pressure sensitive adhesives are particularly preferred.

If the pressure sensitive adhesive layer 22 is configured from an energy ray-curable pressure sensitive adhesive, at a stage where the protective film-forming composite sheet 1 is adhered to an adherend, the energy ray-curable pressure sensitive adhesive may be cured or may not be cured, although it is preferably not cured when taking the preferred storage elastic modulus to be described later into consideration.

The energy ray-curable pressure sensitive adhesive constituting the pressure sensitive adhesive layer 22 may be composed mainly of a polymer having energy ray curability, or may be composed mainly of a mixture of a non-energy ray-curable polymer and an energy ray-curable polyfunctional monomer and/or oligomer.

A case where the energy ray-curable pressure sensitive adhesive includes a polymer having energy ray curability as a main component will be described below.

The polymer having energy ray curability is preferably a (meth)acrylate (co)polymer (A) (hereinafter, may be referred to as an “energy ray-curable polymer (A)”) to which a functional group having energy ray curability (energy ray-curable group) has been introduced in the side chain. The energy ray-curable polymer (A) is preferably obtained by reacting a (meth)acrylic copolymer (a1) having a functional group-containing monomer unit with an unsaturated group-containing compound (a2) having a substituent that binds to the functional group.

The acrylic copolymer (a1) is composed of a structural unit derived from the functional group-containing monomer, and a structural unit derived from a (meth)acrylic acid ester monomer or a derivative thereof.

The functional group-containing monomer serving as a structural unit of the acrylic copolymer (a1) is preferably a monomer having a polymerizable double bond and a functional group such as a hydroxy group, an amino group, a substituted amino group, an epoxy group, and a carboxyl group in the molecule.

More specific examples of the functional group-containing monomers described above include 2-hydroxyethyl (meth)acrylate, 2-hydroxypropyl (meth)acrylate, 3-hydroxypropyl (meth)acrylate, 4-hydroxybutyl (meth)acrylate, glycidyl (meth)acrylate, and acrylic acid, and these are used either alone or in combination of two or more types thereof.

As a (meth)acrylic acid ester monomer constituting the acrylic copolymer (a1), an alkyl (meth)acrylate with an alkyl group having 1 to 20 carbon atoms, cycloalkyl (meth)acrylate or benzyl (meth)acrylate is used. Among these, an alkyl (meth)acrylate with an alkyl group having 1 to 18 carbon atoms such as methyl (meth)acrylate, ethyl (meth)acrylate, propyl (meth)acrylate, n-butyl (meth)acrylate, 2-ethylhexyl (meth)acrylate, or the like is used particularly preferably.

The acrylic copolymer (a1) is formed to include a structural unit derived from the functional group-containing monomer described above usually in a proportion of 3 to 100% by mass and preferably in a proportion of 5 to 40% by mass, and a structural unit derived from a (meth)acrylic acid ester monomer or a derivative thereof usually in a proportion of 0 to 97% by mass and preferably in a proportion of 60 to 95% by mass.

Although the acrylic copolymer (a1) can be obtained by copolymerizing a functional group-containing monomer as described above with a (meth)acrylic acid ester monomer or a derivative thereof in a conventional manner, dimethylacrylamide, vinyl formate, vinyl acetate, styrene, or the like may be copolymerized in addition to these monomers.

By reacting the acrylic copolymer (a1) having the functional group-containing monomer unit described above with the unsaturated group-containing compound (a2) having a substituent that binds to the functional group, the energy ray-curable polymer (A) can be obtained.

The substituent included in the unsaturated group-containing compound (a2) can be selected as appropriate in accordance with the type of the functional group of the functional group-containing monomer unit included in the acrylic copolymer (a1). For example, when the functional group is a hydroxy group, an amino group or a substituted amino group, the substituent is preferably an isocyanate group or an epoxy group, when the functional group is an epoxy group, the substituent is preferably an amino group, a carboxyl group or an aziridinyl group, and when the functional group is a carboxyl group, the substituent is preferably an epoxy group.

In addition, in the unsaturated group-containing compound (a2), 1 to 5 and preferably 1 to 2 energy ray-polymerizable carbon-carbon double bonds are contained per molecule. Specific examples of such unsaturated group-containing compounds (a2) include, for example, 2-methacryloyloxyethyl isocyanate, meta-isopropenyl-α,α-dimethylbenzyl isocyanate, methacryloyl isocyanate, allyl isocyanate, and 1,1-(bisacryloyloxymethyl)ethyl isocyanate; an acryloyl monoisocyanate compound obtained by the reaction of a diisocyanate compound or polyisocyanate compound and hydroxyethyl (meth)acrylate; an acryloyl monoisocyanate compound obtained by the reaction of a diisocyanate compound or polyisocyanate compound, a polyol compound and hydroxyethyl (meth)acrylate; glycidyl (meth)acrylate; (meth)acrylic acid, 2-(1-aziridinyl)ethyl (meth)acrylate, 2-vinyl-2-oxazoline, 2-isopropenyl-2-oxazoline, and the like.

The unsaturated group-containing compound (a2) is used usually in a proportion of 10 to 100 equivalents, and preferably 20 to 95 equivalents, per 100 equivalents of the functional group-containing monomer of the acrylic copolymer (a1) described above.

In the reaction between the acrylic copolymer (a1) and the unsaturated group-containing compound (a2), depending on the combinations of the functional groups and the substituents, the temperature, pressure, solvent and time of the reaction, the presence or absence of a catalyst, and the type of the catalyst can be appropriately selected. As a result, the functional group present in the acrylic copolymer (a1) reacts with the substituent in the unsaturated group-containing compound (a2), and the unsaturated group is introduced into a side chain in the acrylic copolymer (a1) to obtain the energy ray-curable polymer (A).

The weight average molecular weight of the energy ray-curable polymer (A) obtained in this manner is preferably equal to or more than 10,000, more preferably from 150,000 to 1,500,000, and still more preferably from 200,000 to 1,000,000. It should be noted that the weight average molecular weight (Mw) in the present description is a value in terms of polystyrene as measured by a gel permeation chromatography method (GPC method).

Even when the energy ray-curable pressure sensitive adhesive is composed mainly of a polymer having energy ray-curability, the energy ray-curable pressure sensitive adhesive may further contain an energy ray-curable monomer and/or oligomer (B).

As the energy ray-curable monomer and/or oligomer (B), for example, it is possible to use an ester of a polyhydric alcohol and (meth)acrylic acid, or the like.

Examples of the energy ray-curable monomer and/or oligomer (B) include monofunctional acrylic acid esters such as cyclohexyl (meth)acrylate and isobornyl (meth)acrylate, polyfunctional acrylic acid esters such as trimethylolpropane tri(meth)acrylate, pentaerythritol tri(meth)acrylate, pentaerythritol tetra(meth)acrylate, dipentaerythritol hexa(meth)acrylate, 1,4-butanediol di(meth)acrylate, 1,6-hexanediol di(meth)acrylate, polyethylene glycol di(meth)acrylate and dimethylol tricyclodecane di(meth)acrylate, polyester oligo(meth)acrylates, and polyurethane oligo(meth)acrylates.

When blending the energy ray-curable monomer and/or oligomer (B), the content of the energy ray-curable monomer and/or oligomer (B) in the energy ray-curable pressure sensitive adhesive is preferably from 5 to 80% by mass, and particularly preferably from 20 to 60% by mass.

Here, in the case of using ultraviolet rays as the energy rays for curing the energy ray-curable resin composition, it is preferable to add a photopolymerization initiator (C), and by the use of the photopolymerization initiator (C), it is possible to reduce the polymerization curing time and the light irradiation dose.

Specific examples of the photopolymerization initiator (C) include benzophenone, acetophenone, benzoin, benzoin methyl ether, benzoin ethyl ether, benzoin isopropyl ether, benzoin isobutyl ether, benzoin benzoate, methyl benzoin benzoate, benzoin dimethyl ketal, 2,4-diethylthioxanthone, 1-hydroxycyclohexyl phenyl ketone, benzyl diphenyl sulfide, tetramethylthiuram monosulfide, azobisisobutyronitrile, benzyl, dibenzyl, diacetyl, β-chloroanthraquinone, (2,4,6-trimethylbenzyl diphenyl)phosphine oxide, 2-benzothiazole-N,N-diethyldithiocarbamate, oligo{2-hydroxy-2-methyl-1-[4-(1-propenyl)phenyl]propanone}, and 2,2-dimethoxy-1,2-diphenylethan-1-one. These may be used alone, or two or more types thereof may be used in combination.

The photopolymerization initiator (C) is preferably used in an amount within a range of 0.1 to 10 parts by mass, and particularly preferably from 0.5 to 6 parts by mass, with respect to 100 parts by mass of the energy ray-curable copolymer (A) (in the case of including the energy ray-curable monomer and/or oligomer (B), with respect to 100 parts by mass of the total amount of the energy ray-curable copolymer (A) and the energy ray-curable monomer and/or oligomer (B)).

In the energy ray-curable pressure sensitive adhesive, other components may be included as appropriate, in addition to the components described above. Examples of other components include a non-energy ray-curable polymer component or oligomer component (D).

Examples of the non-energy ray-curable polymer component or oligomer component (D) include polyacrylic esters, polyesters, polyurethanes, polycarbonates and polyolefins, and a polymer or oligomer having a weight average molecular weight (Mw) of 3,000 to 2,500,000 is preferred.

In addition, the energy ray-curable pressure sensitive adhesive may form a cross-linked structure by a crosslinking agent (E). As the crosslinking agent (E), a polyfunctional compound that will react with the functional group included in the energy ray-curable copolymer (A) or the like can be used. Examples of such polyfunctional compounds include isocyanate compounds, epoxy compounds, amine compounds, melamine compounds, aziridine compounds, hydrazine compounds, aldehyde compounds, oxazoline compounds, metal alkoxide compounds, metal chelate compounds, metal salts, ammonium salts, and reactive phenol resins.

By using these other components (D) and (E), the tackiness and releasability before curing, the strength after curing, the adhesiveness to other layers, the storage stability and so on may be improved. The amount used of these other components is not particularly limited, and is appropriately determined within a range of 0 to 40 parts by mass with respect to 100 parts by mass of the energy ray-curable copolymer (A).

Next, a case where the energy ray-curable pressure sensitive adhesive is composed mainly of a mixture of a non-energy ray-curable polymer component and an energy ray-curable polyfunctional monomer and/or oligomer will be described below.

As the non-energy ray-curable polymer component, for example, the same components as the acrylic copolymer (a1) described earlier, acrylic copolymers that do not have a functional group-containing monomer as a structural unit but have a (meth)acrylic acid ester monomer or a derivative thereof as a structural unit, and the like can be used. The content of the non-energy ray-curable polymer component in the energy ray-curable resin composition is preferably from 20 to 99.9% by mass, and particularly preferably from 30 to 80% by mass.

As the energy ray-curable polyfunctional monomer and/or oligomer, the same as the component (B) described earlier is selected. The mixing ratio between the non-energy ray-curable polymer component and the energy ray-curable polyfunctional monomer and/or oligomer is preferably from 10 to 150 parts by mass, and particularly preferably from 25 to 100 parts by mass, of the polyfunctional monomer and/or oligomer, with respect to 100 parts by mass of the polymer component.

Also in this case, as described above, the photopolymerization initiator (C) and the crosslinking agent (E) can be used as appropriate.

On the other hand, when an acrylic pressure sensitive adhesive is used as a pressure sensitive adhesive constituting the pressure sensitive adhesive layer 22, as the acrylic pressure sensitive adhesive, for example, the same components as the acrylic copolymer (a1) described earlier, acrylic copolymers that do not have a functional group-containing monomer as a structural unit but have a (meth)acrylic acid ester monomer or a derivative thereof as a structural unit, and the like can be used. In addition, in that case, the acrylic pressure sensitive adhesive may form a cross-linked structure by a crosslinking agent similar to the crosslinking agent (E) described earlier.

Here, the storage elastic modulus at 130° C. of the pressure sensitive adhesive constituting the pressure sensitive adhesive layer 22 is preferably from 1.0×10⁵ to 8.0×10⁶ Pa, more preferably from 3.0×10⁵ to 6.5×10⁶ Pa, and still more preferably from 5.0×10⁵ to 5.0×10⁶ Pa. If the storage elastic modulus at 130° C. of the above adhesive is relatively low as described above, the adhesive force between the pressure sensitive adhesive layer 22 and the protective film-forming film 3 can be kept high even in the heating step, the amount of misalignment between the pressure sensitive adhesive layer 22 and the protective film-forming film 3 is reduced, and the loosening of the protective film-forming composite sheet 1 can be suppressed more effectively. As a result, it is possible to effectively prevent incomplete restoration of the protective film-forming composite sheet 1 due to the shrinkage at the time of cooling. It should be noted that the method of measuring the storage elastic modulus in the present description is as shown in test examples described later.

When an acrylic pressure sensitive adhesive is used as the pressure sensitive adhesive constituting the pressure sensitive adhesive layer 22, the pressure sensitive adhesive layer 22 may further contain an epoxy resin. When constituting the pressure sensitive adhesive layer 22 using an acrylic pressure sensitive adhesive, a curable pressure sensitive adhesive constituting the protective film-forming film 3 adjacent to the pressure sensitive adhesive layer 22 may migrate to the pressure sensitive adhesive layer 22 to change the physical properties of the pressure sensitive adhesive layer 22. However, since the pressure sensitive adhesive layer 22 contains an epoxy resin, it becomes possible to prevent changes in the physical properties due to the migration of the curable pressure sensitive adhesive.

In the case described above, the content of the epoxy resin in the pressure sensitive adhesive layer 22 is preferably greater than 0 parts by mass and equal to or less than 20 parts by mass, and particularly preferably from 1 to 17 parts by mass, with respect to 100 parts by mass of the acrylic copolymer.

### 1-2. Base Material

The base material 21 of the pressure sensitive adhesive sheet 2 is preferably constituted from a material hardly loosened by heating or a material easily restored by cooling even if loosened by heating, which is also suitable for processing of a workpiece, for example, dicing and expanding of a semiconductor wafer, and is usually constituted of a film which is composed primarily of a resin-based material (hereinafter, referred to as a “resin film”).

Specific examples of the resin film include polyolefin-based films such as a polyethylene film including a low density polyethylene (LDPE) film, a linear low density polyethylene (LLDPE) film and a high density polyethylene (HDPE) film, a polypropylene film, a polybutene film, a polybutadiene film, a polymethylpentene film, an ethylene-norbornene copolymer film and a norbornene resin film; ethylene-based copolymer films such as an ethylene-vinyl acetate copolymer film, an ethylene-(meth)acrylic acid copolymer film and an ethylene-(meth)acrylate copolymer film; polyvinyl chloride-based films such as a polyvinyl chloride film and a vinyl chloride copolymer film; polyester-based films such as a polyethylene terephthalate film and a polybutylene terephthalate film; a polyurethane film; a polyimide film; a polystyrene film; a polycarbonate film; and a fluorine resin film. In addition, modified films such as cross-linked films and ionomer films of these are also used. The above base material 21 may be a film composed of one type of these, or may be a laminated film obtained by combining two or more types of these. It should be noted that the term “(meth)acrylic acid” in the present description means both acrylic acid and methacrylic acid. The same applies to other similar terms.

Among those described above, a polyolefin-based film or a laminated film obtained by combining a polyolefin-based film with other films is preferred, a polyethylene film, a polypropylene film, or a laminated film obtained by combining these with other films is more preferred, and a polypropylene film is still more preferred. By using the polyolefin-based film, it is possible to reduce the base material debris (cut debris) produced by cutting the base material with a dicing blade at the time of dicing. In addition, when the protective film-forming composite sheet 1 adhered to the workpiece is subjected to a heating step, the polypropylene film exhibits moderate heat resistance and therefore tends to shrink at the time of cooling and be restored to the original state, even if the loosening occurs in the polypropylene film used as the base material 21. Furthermore, since the polypropylene film exhibits moderate flexibility, there is a tendency that the expanding step and the pickup step after dicing can be performed satisfactorily.

For the purpose of improving the adhesion with the pressure sensitive adhesive layer 22 laminated on the surface, if desired, one or both sides of the above resin film can be subjected to a surface treatment by an oxidation method, a roughening method or the like, or to a primer treatment. Examples of the above oxidation method include a corona discharge treatment, a plasma discharge treatment, a chromium oxidation treatment (wet), a flame treatment, a hot air treatment, an ozone treatment, and an ultraviolet irradiation treatment. In addition, as the roughening method, for example, a sand blasting method, a thermal spraying treatment method, and the like can be mentioned.

The base material 21 may contain, in the above resin film, various additives such as coloring agents, flame retardants, plasticizers, antistatic agents, lubricants and fillers.

The thickness of the base material 21 is not particularly limited as long as it is able to function suitably in each step where the protective film-forming composite sheet 1 is used, and is either hardly loosened by heating or easily restored by cooling even if being loosened. The thickness is preferably in the range of 20 to 450 μm, more preferably from 25 to 400 μm, and particularly preferably from 50 to 350 μm.

### 2. Protective Film-Forming Film

The protective film-forming film 3 is preferably composed of an uncured curable pressure sensitive adhesive. In this case, by curing the protective film-forming film 3 after superposing a workpiece such as a semiconductor wafer onto the protective film-forming film 3, it is possible to firmly adhere a protective film to the workpiece, so that a protective film having durability can be formed on a chip or the like. Even when the curable pressure sensitive adhesive is in an uncured stage or in a stage after curing, it is possible to perform printing satisfactorily on the protective film-forming film 3 by laser beam irradiation.

It is preferable that the protective film-forming film 3 either has tackiness at normal temperature, or exhibits tackiness when being heated. Thus, when superposing the workpiece such as a semiconductor wafer onto the protective film-forming film 3 as described above, they can be adhered to each other. Therefore, the positioning of the protective film-forming film 3 prior to curing can be performed reliably, and the handling of the protective film-forming composite sheet 1 is facilitated.

The curable pressure sensitive adhesive constituting the protective film-forming film 3 having characteristics as described above preferably contains a curable component and a binder polymer component. As the curable component, a thermosetting component, an energy ray-curable component, or a mixture thereof can be used, but it is particularly preferable to use a thermosetting component when considering the curing method of the protective film-forming film 3 and the heat resistance after curing.

Examples of the thermosetting component include epoxy resins, phenolic resins (those with low molecular weight), melamine resins, urea resins, polyester resins, urethane resins, acrylic resins, polyimide resins, benzoxazine resins, and the like, and mixtures thereof. Among these, epoxy resins, phenolic resins and mixtures thereof are preferably used. As the thermosetting component, those having a molecular weight of about 300 to 10,000 are usually used.

Epoxy resins have a property of forming a three-dimensional network when heated to form a solid coating film. As the epoxy resin, various known epoxy resins have been conventionally used, although those having a molecular weight of about 300 to 2,500 are usually preferred. Furthermore, an epoxy resin which is in a liquid form in an ordinary state and has a molecular weight of 300 to 500, and an epoxy resin which is solid at normal temperature and has a molecular weight of 400 to 2,500, preferably from 500 to 2,000, are preferably used in the form of a mixture. In addition, the epoxy equivalent of the epoxy resin is preferably from 50 to 5,000 g/eq.

Specific examples of such epoxy resins include glycidyl ethers of phenols, such as bisphenol A, bisphenol F, resorcinol, phenyl novolac and cresol novolac; glycidyl ethers of alcohols, such as butanediol, polyethylene glycol, and polypropylene glycol; glycidyl ethers of carboxylic acids, such as phthalic acid, isophthalic acid, and tetrahydrophthalic acid; glycidyl-type or alkyl glycidyl-type epoxy resins in which the active hydrogen bonded to the nitrogen atom of aniline isocyanurate and the like is substituted with a glycidyl group; and the so-called alicyclic epoxides in which an epoxy moiety is introduced by, for example, oxidizing the carbon-carbon double bond in the molecule, such as vinyl cyclohexane diepoxide, 3,4-epoxycyclohexylmethyl-3,4-dicyclohexanecarboxylate, and 2-(3,4-epoxy)cyclohexyl-5,5-spiro(3,4-epoxy)cyclohexane-m-dioxane. In addition, it is also possible to use an epoxy resin having a biphenyl skeleton, a dicyclohexadiene skeleton, a naphthalene skeleton, or the like.

Of these, bisphenol-based glycidyl type epoxy resins, o-cresol novolac-type epoxy resins and phenol novolac-type epoxy resin are preferably used. One type of these epoxy resins may be used alone or two or more types thereof may be used in combination.

In the case of using an epoxy resin, as an auxiliary agent, it is preferable to use a thermally active latent epoxy resin curing agent concomitantly. The thermally active latent epoxy resin curing agent refers to a type of curing agent that does not react with an epoxy resin at room temperature, is activated by heating to a certain temperature or more, and reacts with the epoxy resin. As a method of activating a thermally active latent epoxy resin curing agent, a method of generating active species (anions and cations) in a chemical reaction by heating; a method in which the curing agent is stably dispersed in the epoxy resin at around room temperature but is dissolved in (compatible with) the epoxy resin at high temperatures to thereby initiate a curing reaction; a method in which a molecular sieve-enclosed type of curing agent is eluted at high temperatures to thereby initiate a curing reaction; a method using a microcapsule, or the like is available.

Specific examples of the thermally active latent epoxy resin curing agents include various onium salts, and high-melting-point active hydrogen compounds such as dibasic acid dihydrazide compounds, dicyandiamide, amine adduct curing agents, and imidazole compounds. One type of these thermally active latent epoxy resin curing agents may be used alone, or two or more types thereof may be used in combination. The thermally active latent epoxy resin curing agent as described above is used in a proportion of, with respect to 100 parts by weight of the epoxy resin, preferably from 0.1 to 20 parts by weight, more preferably from 0.2 to 10 parts by weight, and still more preferably from 0.3 to 5 parts by weight.

As the phenolic resins, polymers having a phenolic hydroxyl group, such as condensates of phenols and aldehydes, including alkylphenols, polyhydric phenols, naphthol, and the like are used without particular limitations. More specifically, phenol novolac resins, o-cresol novolac resins, p-cresol novolac resins, t-butylphenol novolac resins, dicyclopentadiene cresol resins, polyparavinylphenol resins, bisphenol A type novolac resins, or their modified products and the like are used.

The phenolic hydroxyl groups contained in these phenolic resins can easily cause an addition reaction by heating with an epoxy group of the epoxy resin described above to form a cured product with high impact resistance. For this reason, an epoxy resin and a phenolic resin may be used in combination.

The binder polymer component is added with an aim of providing the protective film-forming film 3 with moderate tackiness, improving the operability of the protective film-forming composite sheet 1, and the like. The weight average molecular weight of the binder polymer is usually in the range of 30,000 to 2,000,000, preferably from 50,000 to 1,500,000, and particularly preferably from 100,000 to 1,000,000. By setting the molecular weight to 30,000 or higher, the film formation of the protective film-forming film 3 becomes sufficient. By setting the molecular weight to 2,000,000 or less, compatibility with other components is favorably maintained, and the film formation of the protective film-forming film 3 can be performed uniformly. As the binder polymer, for example, acrylic polymers, polyester resins, phenoxy resins, urethane resins, silicone resins, rubber-based polymers, and the like are used, and acrylic polymers are particularly preferably used.

Examples of the acrylic polymers include (meth)acrylic acid ester copolymers composed of a (meth)acrylic acid ester monomer and a structural unit derived from a (meth)acrylic acid derivative. Here, as the (meth)acrylic acid ester monomer, (meth)acrylic acid alkyl esters, preferably with an alkyl group having 1 to 18 carbon atoms, such as methyl (meth)acrylate, ethyl (meth)acrylate, propyl (meth)acrylate, butyl (meth)acrylate, and the like are used. In addition, as the (meth)acrylic acid derivative, for example, (meth)acrylic acid, glycidyl (meth)acrylate, hydroxyethyl (meth)acrylate, and the like can be mentioned.

When a glycidyl group is introduced into the acrylic polymer by using glycidyl methacrylate and the like, among those described above, as structural units, the compatibility with the epoxy resin serving as the thermosetting component as described earlier is improved, and the glass transition temperature (Tg) of the protective film-forming film 3 after curing becomes higher, thereby improving the heat resistance. In addition, when a hydroxyl group is introduced into the acrylic polymer by using hydroxyethyl acrylate and the like, among those described above, as structural units, it is possible to control the adhesion and tackiness to the workpiece. It should be noted that in the case of introducing a glycidyl group into the acrylic polymer by using glycidyl methacrylate and the like as structural units, the resulting acrylic polymer and a phenoxy resin having an epoxy group exhibit thermosetting properties. However, polymers exhibiting such thermosetting properties are also regarded as the binder polymer component in the present embodiment, instead of the thermosetting component.

In the case of using an acrylic polymer as the binder polymer, the weight average molecular weight of the polymer is preferably equal to or more than 100,000, and particularly preferably from 150,000 to 1,000,000. The glass transition temperature of the acrylic polymer is usually equal to or less than 20° C. and preferably from about −70 to 0° C., and the polymer has tackiness at normal temperature (23° C.).

The mixing ratio between the thermosetting component and the binder polymer component is such that the thermosetting component is included, with respect to 100 parts by weight of the binder polymer component, preferably from 50 to 1,500 parts by weight, more preferably from 70 to 1,000 parts by weight, and still more preferably from 80 to 800 parts by weight. When the thermosetting component and the binder polymer component are mixed in such a ratio, moderate tackiness is achieved before curing, an adhering operation can be performed in a stable manner, and a protective film with superior film strength can be obtained after curing.

The protective film-forming film 3 preferably contains a filler and/or a coloring agent. When the protective film-forming film 3 contains a filler, it is possible to maintain the hardness of the protective film at a high level after curing, while improving the moisture resistance. In addition, the surface gloss of the protective film to be formed can also be adjusted to a desired value. Furthermore, the thermal expansion coefficient of the protective film after curing can be brought close to the thermal expansion coefficient of the semiconductor wafer, as a result of which the warpage of a semiconductor wafer in the middle of the processing can be reduced. On the other hand, when the protective film-forming film 3 contains a filler and/or a coloring agent, it is also possible to allow for laser printing with excellent visibility.

Examples of the fillers include inorganic fillers such as silica including crystalline silica, fused silica and synthetic silica, alumina, and glass balloons. Among them, synthetic silica is preferred, and especially a type of synthetic silica from which an a ray source causing malfunction of the semiconductor device has been removed as much as possible is most suitable. The shape of the filler may be any of spherical, needle-like, and amorphous shapes.

Further, as the filler to be added to the protective film-forming film 3, in addition to the above inorganic fillers, a functional filler may be blended. Examples of the functional fillers include electrically conductive fillers such as gold, silver, copper, nickel, aluminum, stainless steel, carbon, ceramic, and those obtained by coating nickel, aluminum or the like with silver, with an aim to impart antistatic properties; and thermally conductive fillers including metal materials such as gold, silver, copper, nickel, aluminum, stainless steel, silicon, and germanium, alloys thereof, and the like, with an aim to impart thermal conductivity.

As the coloring agent, it is possible to use known agents, such as inorganic pigments, organic pigments and organic dyes.

Examples of the inorganic pigments include carbon black, cobalt-based pigments, iron-based pigments, chromium-based pigments, titanium-based pigments, vanadium-based pigments, zirconium-based pigments, molybdenum-based pigments, ruthenium-based pigments, platinum-based pigments, ITO (indium tin oxide)-based pigments, and ATO (antimony tin oxide)-based pigments.

As the organic pigments and organic dyes, for example, aminium-based pigments, cyanine-based pigments, merocyanine-based pigments, croconium-based pigments, squarylium-based pigments, azulenium-based pigments, polymethine-based pigments, naphthoquinone-based pigments, pyrylium-based pigments, phthalocyanine-based pigments, naphthalocyanine-based pigments, naphtholactam-based pigments, azo-based pigments, condensed azo-based pigments, indigo-based pigments, perinone-based pigments, perylene-based pigments, dioxazine-based pigments, quinacridone-based pigments, isoindolinone-based pigments, quinophthalone-based pigments, pyrrole-based pigments, thioindigo-based pigments, metal complex-based pigments (metal complex salt dyes), dithiol metal complex-based pigments, indole phenol-based pigments, triallylmethane-based pigments, anthraquinone-based pigments, dioxazine-based pigments, naphthol-based pigments, azomethine-based pigments, benzimidazolone-based pigments, pyranthrone-based pigments, threne-based pigments, and the like may be mentioned. These pigments or dyes can be used by mixing as appropriate in order to adjust the light transmittance to an intended level.

Among those described above, it is preferable to use a pigment, especially an inorganic pigment, in view of the printing properties by laser beam irradiation. Among the inorganic pigments, carbon black is particularly preferred. Although carbon black is usually black, since a portion scraped away by laser beam irradiation becomes white and the contrast difference is increased, visibility of the laser printed portion is highly excellent.

The added amounts of the filler and coloring agent in the protective film-forming film 3 may be suitably adjusted, so that the desired effects can be achieved. More specifically, the added amount of the filler is usually preferably from 40 to 80% by mass, and particularly preferably from 50 to 70% by mass. In addition, the added amount of the coloring agent is usually preferably from 0.001 to 5% by mass, more preferably from 0.01 to 3% by mass, and still more preferably from 0.1 to 2.5% by mass.

The protective film-forming film 3 may contain a coupling agent. By containing a coupling agent, after curing the protective film-forming film 3, it is possible to improve the adhesive properties and adhesion between the protective film and the workpiece while improving the water resistance (wet heat resistance) without impairing the heat resistance of the protective film. As the coupling agent, a silane coupling agent is preferred because of its versatility, cost merits, and the like.

Examples of the silane coupling agent include γ-glycidoxypropyltrimethoxysilane, γ-glycidoxypropylmethyldiethoxysilane, β-(3,4-epoxycyclohexyl)ethyl trimethoxysilane, γ-(methacryloxypropyl) trimethoxysilane, γ-aminopropyltrimethoxysilane, N-6-(aminoethyl)-γ-aminopropyltrimethoxysilane, N-6-(aminoethyl)-γ-aminopropyl methyldiethoxysilane, N-phenyl-γ-aminopropyltrimethoxysilane, γ-ureidopropyltriethoxysilane, γ-mercaptopropyltrimethoxysilane, γ-mercaptopropylmethyldimethoxysilane, bis(3-triethoxysilylpropyl) tetrasulfane, methyltrimethoxysilane, methyltriethoxysilane, vinyltrimethoxysilane, vinyltriacetoxysilane, and imidazolesilane. One type of these may be used alone or two or more types thereof may be mixed and used.

The protective film-forming film 3 may contain a crosslinking agent such as organic polyvalent isocyanate compounds, organic polyvalent imine compounds and organic metal chelate compounds, in order to adjust the cohesive force prior to curing. In addition, the protective film-forming film 3 may contain an antistatic agent, in order to suppress the static electricity and to improve the chip reliability. Furthermore, the protective film-forming film 3 may contain a flame retardant such as phosphate compounds, bromine compounds and phosphorus-based compounds, in order to increase the flame retardancy of the protective film and to improve the reliability as a package.

The thickness of the protective film-forming film 3 is preferably from 3 to 300 μm, more preferably from 5 to 250 μm, and still more preferably from 7 to 200 μm, in order to effectively bring about the function as a protective film.

Here, in the case of forming a protective film by curing the protective film-forming film 3 while being in contact with the pressure sensitive adhesive layer 22 in the pressure sensitive adhesive sheet 2, the surface gloss value on the pressure sensitive adhesive sheet 2 side in the protective film is preferably equal to or greater than 25, and particularly preferably equal to or greater than 30. It should be noted that the gloss values in the present description are values measured using a glossmeter at a measuring angle of 60° in accordance with its Z8741. When the surface gloss value of the protective film formed on a chip is within the above range, excellent aesthetic appearance as well as excellent visibility of the print to be formed by laser printing can be achieved.

### 3. Pressure Sensitive Adhesive Layer for Jigs

The protective film-forming composite sheet 1 according to the present embodiment includes a pressure sensitive adhesive layer 4 for jigs in a peripheral edge portion on the side opposite to the pressure sensitive adhesive sheet 2 side of the protective film-forming film 3. By including the pressure sensitive adhesive layer 4 for jigs as described above, regardless of the adhesive force of the protective film-forming film 3, the protective film-forming composite sheet 1 can be reliably fixed by adhering to a jig such as a ring frame.

The pressure sensitive adhesive layer 4 for jigs in the present embodiment is formed into a circular shape. Here, as shown in FIG. 2, when the protective film-forming film 3 of the protective film-forming composite sheet 1 is adhered to the workpiece 5 (shown to have a circular shape in plan view in FIG. 2, but is not limited thereto), the pressure sensitive adhesive layer 4 for jigs is preferably formed in such a manner that a gap w₁ in the planar direction between the main outer peripheral edge of the workpiece 5 (for example, when the workpiece 5 is a semiconductor wafer, the outer peripheral edge excluding the notches or the like for specifying the crystal orientation) and the inner peripheral edge of the pressure sensitive adhesive layer 4 for jigs is less than 10 mm. When the workpiece 5 is a semiconductor wafer, the main outer peripheral edge of the workpiece 5 usually has a circular shape. If the inner peripheral edge of the pressure sensitive adhesive layer 4 for jigs is formed into a circular shape, the semiconductor wafer is typically bonded in such a manner that the main outer peripheral edge thereof and the inner peripheral edge of the pressure sensitive adhesive layer 4 for jigs form concentric circles. In this case, the gap w₁ in the planar direction between the main outer peripheral edge of the workpiece 5 and the inner peripheral edge of the pressure sensitive adhesive layer 4 for jigs is constant.

Although the protective film-forming composite sheet 1 tends to be loosened in the gap portion described above, because the gap w₁ described above is as small as less than 10 mm, when the workpiece and the protective film-forming composite sheet 1 adhered to a jig such as a ring frame are subjected to a heating step, there is a tendency that the pressure sensitive adhesive layer 4 for jigs reduces the load due to the weight of the workpiece, and restoration of the loosening is also promoted. As a result, loosening of the protective film-forming composite sheet 1 can be suppressed more effectively.

From this viewpoint, the gap w₁ described above is more preferably from 0 to 8 mm, and particularly preferably from 1 to 7 mm. In addition, if the workpiece 5 is a semiconductor wafer and the inner peripheral edge of the pressure sensitive adhesive layer 4 for jigs is formed into a circular shape, when the diameter of the inner peripheral edge of the pressure sensitive adhesive layer 4 for jigs is defined as d₁ and the diameter of the main outer peripheral edge of the workpiece 5 is defined as d₂, (d₁-d₂) is preferably less than 20 mm, more preferably from 0 to 16 mm, and particularly preferably from 2 to 14 mm.

It should be noted that when the storage elastic modulus at 130° C. of the pressure sensitive adhesive constituting the pressure sensitive adhesive layer 22 is from 1.0×10⁵ to 8.0×10⁶ Pa, even if the gap w₁ is not less than 10 mm as described above, loosening of the protective film-forming composite sheet 1 can be effectively prevented at the same level as described above.

The pressure sensitive adhesive layer 4 for jigs may be composed of a single layer, or may be composed of a multilayer consisted of two or more layers. In the case of two or more layers, a configuration in which a core material is inserted therebetween is preferred.

The pressure sensitive adhesive constituting the pressure sensitive adhesive layer 4 for jigs is preferably composed of a non-energy ray-curable pressure sensitive adhesive, in view of the adhesive force to a jig such as a ring frame. As the non-energy ray-curable pressure sensitive adhesive, one having the desired adhesive force and removability is preferred, and it is possible to use, for example, acrylic pressure sensitive adhesives, rubber-based pressure sensitive adhesives, silicone-based pressure sensitive adhesives, urethane-based pressure sensitive adhesives, polyester-based pressure sensitive adhesives, polyvinyl ether-based pressure sensitive adhesives, or the like. Among these, acrylic pressure sensitive adhesives are preferred with which the adhesive force and removability are easily controlled.

As the core material, resin films are usually used. Among these, polyvinyl chloride-based films such as a polyvinyl chloride film and a vinyl chloride copolymer film are preferred, and a polyvinyl chloride film is particularly preferred. The polyvinyl chloride films have properties of being easily restored when cooled, even if being heated and softened. The thickness of the core material is preferably from 2 to 200 μm, and particularly preferably from 5 to 100 μm.

The thickness of the pressure sensitive adhesive layer 4 for jigs is preferably from 5 to 200 μm, and particularly preferably from 10 to 100 μm, from the viewpoint of the adhesiveness to a jig such as a ring frame.

### 4. Release Sheet

The protective film-forming composite sheet 1 may have a release sheet on the side of the protective film-forming film 3 and the pressure sensitive adhesive layer 4 for jigs (upper side in FIG. 1). According to such a release sheet, it is possible to protect the protective film-forming film 3 and the pressure sensitive adhesive layer 4 for jigs during the period until the protective film-forming composite sheet 1 is used.

The configuration of the release sheet is optional, and examples thereof include those obtained by subjecting a plastic film to a release treatment using a release agent and the like. Specific examples of the plastic film include polyester films composed of polyethylene terephthalate, polybutylene terephthalate, polyethylene naphthalate, and the like, and polyolefin films composed of polypropylene, polyethylene, and the like. As the release agent, it is possible to use silicone-based agents, fluorine-based agents, long chain alkyl-based agents, and the like, although among these, silicone-based agents which can achieve stable performance at a low cost are preferred. The thickness of the release sheet is not particularly limited, although it is usually from about 20 to 250 μm.

### 5. Method of Producing Protective Film-Forming Composite Sheet

The protective film-forming composite sheet 1 can be produced, preferably, by preparing each of a first laminate including the protective film-forming film 3, a second laminate including the pressure sensitive adhesive sheet 2, and a third laminate including the pressure sensitive adhesive layer 4 for jigs, then laminating the protective film-forming film 3 and the pressure sensitive adhesive sheet 2 by using the first laminate and the second laminate, and further laminating the pressure sensitive adhesive layer 4 for jigs using the third laminate, although the process is not limited thereto.

In order to produce the first laminate, the protective film-forming film 3 is formed on a release surface (the surface having releasability; which is usually a surface subjected to a release treatment, but is not limited thereto) of a first release sheet. More specifically, a coating agent for the protective film-forming film that contains the curable pressure sensitive adhesive constituting the protective film-forming film 3, and a solvent according to need, is prepared, and is then coated and dried on the release surface of the first release sheet using a coater such as a roll coater, a knife coater, a roll knife coater, an air knife coater, a die coater, a bar coater, a gravure coater, and a curtain coater, to thereby form the protective film-forming film 3. Then, a release surface of the second release sheet is superimposed on and pressure bonded to the exposed surface of the protective film-forming film 3, to thereby obtain a laminated body (first laminate) in which the protective film-forming film 3 is sandwiched between the two release sheets.

In order to produce the second laminate, a coating agent for the pressure sensitive adhesive layer that contains the pressure sensitive adhesive constituting the pressure sensitive adhesive layer 22 and a solvent according to need is coated and dried on the release surface of the release sheet, to thereby form the pressure sensitive adhesive layer 22. Thereafter, the base material 21 is pressure bonded on the exposed surface of the pressure sensitive adhesive layer 22 to yield a laminated body (second laminate) which is configured of the pressure sensitive adhesive sheet 2 composed of the base material 21 and the pressure sensitive adhesive layer 22, and the release sheet.

Here, in those cases where the pressure sensitive adhesive layer 22 is composed of an energy ray-curable pressure sensitive adhesive, it is also preferable to cure the energy ray-curable pressure sensitive adhesive by irradiating an energy ray onto the pressure sensitive adhesive layer 22. In addition, in those cases where the pressure sensitive adhesive layer 22 is composed of a multilayer, and the layer which comes into contact with the protective film-forming film 3 is composed of an energy ray-curable pressure sensitive adhesive, the energy ray-curable pressure sensitive adhesive may be cured by irradiating an energy ray onto the contact layer.

As the energy ray, typically, ultraviolet rays, electron rays, and the like are used. The exposure dose of energy rays varies depending on the type of energy rays, although in the case of ultraviolet rays, for example, it is preferably from 50 to 1,000 mJ/cm² in light quantity, and particularly preferably from 100 to 500 mJ/cm². In addition, in the case of electron rays, it is preferably about 10 to 1,000 krad.

In order to produce the third laminate when the pressure sensitive adhesive layer 4 for jigs is a single layer, the pressure sensitive adhesive layer 4 for jigs is formed on the release surface of the first release sheet. More specifically, a coating agent for the pressure sensitive adhesive layer for jigs that contains the pressure sensitive adhesive constituting the pressure sensitive adhesive layer 4 for jigs and a solvent according to need is prepared, and is then coated and dried on the release surface of the first release sheet, to thereby form the pressure sensitive adhesive layer 4 for jigs. Then, a release surface of the second release sheet is superimposed on and pressure bonded to the exposed surface of the pressure sensitive adhesive layer 4 for jigs, to thereby obtain a laminated body (third laminate) in which the pressure sensitive adhesive layer 4 for jigs is sandwiched between the two release sheets.

In order to produce the third laminate when the pressure sensitive adhesive layer 4 for jigs has a core material, for example, a first pressure sensitive adhesive layer for jigs is formed on the release surface of the first release sheet, and the core material is laminated on the first pressure sensitive adhesive layer for jigs. In addition, a second pressure sensitive adhesive layer for jigs is formed on the release surface of the second release sheet. Then, the second pressure sensitive adhesive layer for jigs and the core material on the first pressure sensitive adhesive layer for jigs are superimposed to pressure bond the two laminates. As a result, a laminated body (third laminate) formed by sandwiching the pressure sensitive adhesive layer 4 for jigs which has a core material between the two release sheets can be obtained.

When the first laminate, the second laminate and the third laminate are obtained as described above, the release sheet in the second laminate is peeled off, while peeling off the second release sheet in the first laminate, and the protective film-forming film 3 which is exposed in the first laminate and the pressure sensitive adhesive layer 22 of the pressure sensitive adhesive sheet 2 which is exposed in the second laminate are superimposed and pressure bonded (fourth laminate).

On the other hand, as for the third laminate, the inner peripheral edges of the second release sheet and the pressure sensitive adhesive layer 4 for jigs are subjected to a half-cutting process, while leaving the first release sheet. The second release sheet and the excess portions (circular portion) of the pressure sensitive adhesive layer 4 for jigs which is produced by the half-cutting process may be removed as appropriate. Then, the first release sheet is peeled off from the fourth laminate, and the exposed protective film-forming film 3 and the pressure sensitive adhesive layer 4 for jigs which is exposed in the third laminate are superimposed and pressure bonded. Thereafter, the outer peripheral edge of the protective film-forming composite sheet 1 is subjected to a half-cutting process, while leaving the first release sheet in the third laminate.

In this manner, one formed by laminating a release sheet, on the protective film-forming composite sheet 1 composed of the pressure sensitive adhesive sheet 2 formed by laminating the pressure sensitive adhesive layer 22 on the base material 21; the protective film-forming film 3 laminated on the pressure sensitive adhesive layer 22 side of the pressure sensitive adhesive sheet 2; and the pressure sensitive adhesive layer 4 for jigs which is laminated on a periphery portion on the side opposite to the pressure sensitive adhesive sheet 2 in the protective film-forming film 3, can be obtained. In this case, the release sheet is laminated on the side opposite to the protective film-forming film 3 in the pressure sensitive adhesive layer 4 for jigs.

Since the sizes and shapes of the protective film-forming film 3 and the pressure sensitive adhesive sheet 2 can be made the same, as compared to those in which their sizes or shapes are different, the protective film-forming composite sheet 1 having the configuration as described above can be easily produced with fewer steps in the half-cutting process.

In addition, in the protective film-forming composite sheet 1 having the configuration as described above, since the protruded outer peripheral edge of the pressure sensitive adhesive layer 4 for jigs and the outer peripheral edge of the protective film-forming composite sheet 1 as a whole can be made at the same position, when a long release sheet (process film) supporting a plurality of the protective film-forming composite sheets 1 according to the present embodiment is rolled up, there is an advantage in that formation of the so-called winding marks hardly occurs.

### 6. Method of Using Protective Film-Forming Composite Sheet

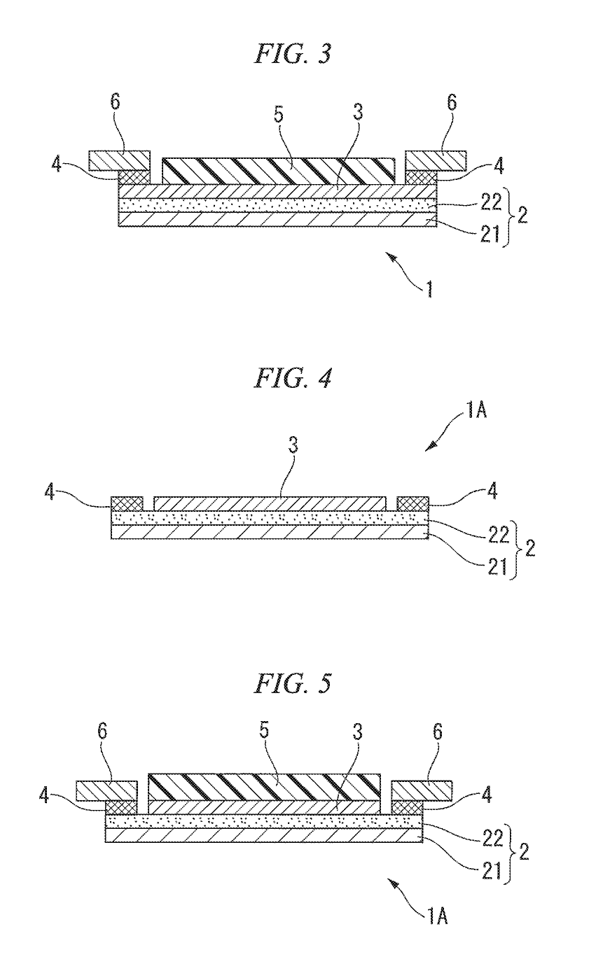

Using the protective film-forming composite sheet 1 according to the present embodiment, a method of producing a chip with a protective film from a semiconductor wafer serving as a workpiece will be described below as an example. First, as shown in FIG. 3, the protective film-forming film 3 is adhered to a semiconductor wafer 5, while adhering the pressure sensitive adhesive layer 4 for jigs to ring frames 6. When adhering the protective film-forming film 3 onto the semiconductor wafer 5, if desired, the protective film-forming film 3 may be heated to exert tackiness.

Then, the protective film-forming film 3 is cured to form a protective film. When the protective film-forming film 3 is a thermosetting adhesive, the protective film-forming film 3 is heated for an appropriate period of time at a predetermined temperature, and is then cooled. At this time, the protective film-forming composite sheet 1 according to the present embodiment is less likely to cause troubles in subsequent steps, since the loosening is effectively suppressed.

The protective film-forming film 3 before curing or the protective film-forming film 3 after curing (protective film) may be subjected to laser printing, if desired. Thereafter, the semiconductor wafer 5 is subjected to dicing in accordance with a conventional method to obtain a chip having a protective film (chip with a protective film). Then, if desired, the pressure sensitive adhesive sheet 2 is expanded in the planar direction to pick up the chip with a protective film from the pressure sensitive adhesive sheet 2. Since the protective film-forming composite sheet 1 according to the present embodiment has the pressure sensitive adhesive layer 22 and the pressure sensitive adhesive layer 4 for jigs, it is possible to suppress the occurrence of chip flying during the dicing process described above, the picking up of chips after dicing from becoming difficult, or the occurrence of chipping or detachment of protective film in the chips obtained by the pickup.

### Second Embodiment

FIG. 4 is a cross sectional view of a protective film-forming composite sheet according to a second embodiment of the present invention. As shown in FIG. 4, a protective film-forming composite sheet 1A according to the present embodiment is configured by including a pressure sensitive adhesive sheet 2 formed by laminating a pressure sensitive adhesive layer 22 on one surface of a base material 21, a protective film-forming film 3 laminated on the central portion of the pressure sensitive adhesive layer 22 side of the pressure sensitive adhesive sheet 2, and a pressure sensitive adhesive layer 4 for jigs which is laminated on the peripheral edge portion of the pressure sensitive adhesive layer 22 side of the pressure sensitive adhesive sheet 2.

In the present embodiment, as shown in FIG. 4, the base material 21 and the pressure sensitive adhesive layer 22 of the pressure sensitive adhesive sheet 2 are formed into the same size and shape, which is a circular shape in plan view, although the present invention is not limited thereto. On the other hand, the protective film-forming film 3 is formed so as to be approximately the same size as the workpiece or slightly larger than the workpiece in the surface direction, and also to be smaller than the pressure sensitive adhesive sheet 2 in the surface direction. In addition, in the present embodiment, as shown in FIG. 4, the pressure sensitive adhesive layer 4 for jigs is formed into a circular shape, and the outer peripheral edge thereof is in the same position in plan view as an outer peripheral edge of the pressure sensitive adhesive sheet 2 and the protective film-forming film 3, although the present invention is not limited thereto.

The material and thickness of each layer in the protective film-forming composite sheet 1A according to the present embodiment, and the size thereof, except for the protective film-forming film 3, are the same as those of the first protective film-forming composite sheet 1. Therefore, also with the protective film-forming composite sheet 1A according to the present embodiment, like the first protective film-forming composite sheet 1, the loosening in the heating step and the cooling step can be effectively suppressed, and the dicing and picking up can also be performed satisfactorily.

The protective film-forming composite sheet 1A according to the present embodiment can basically be produced in the same manner as the first protective film-forming composite sheet 1, although a step of subjecting the outer peripheral edge of the protective film-forming film 3 in the fourth laminate to a half-cutting process and removing the outer portion is required.

In order to use the protective film-forming composite sheet 1A according to the present embodiment, as shown in FIG. 5, the protective film-forming film 3 is adhered to a semiconductor wafer 5, while adhering the pressure sensitive adhesive layer 4 for jigs to ring frames 6. Thereafter, it is possible to produce a chip with a protective film in the same manner as the first protective film-forming composite sheet 1.

The embodiments described above have been described in order to facilitate the understanding of the present invention and have not been described to limit the present invention. Therefore, the elements disclosed in the above embodiments are deemed to also include all design modifications and equivalents falling within the technical scope of the present invention.

For example, the pressure sensitive adhesive layer 4 for jigs may have a two-layer configuration consisted of a base material and a pressure sensitive adhesive layer. In this case, it is preferably configured so as to adhere the base material described above to the protective film-forming film 3 exhibiting tackiness, and also to adhere the pressure sensitive adhesive layer described above to a jig such as a ring frame.

### EXAMPLES

Hereinafter, the present invention will be described in more detail using examples and the like, although the scope of the present invention is not limited to these examples and the like.

### Example 1

In Example 1, a protective film-forming composite sheet 1 as shown in FIG. 1 was produced as described below.

(1) Preparation of First Laminate including Protective Film-Forming Film

The following components (a) to (f) were mixed and diluted with methyl ethyl ketone so that the solid content concentration was 50% by mass, thereby preparing a coating agent for a protective film-forming film.

(a) Binder polymer: (meth)acrylic acid ester copolymer (copolymer obtained by copolymerizing 55 parts by mass of butyl acrylate, 10 parts by mass of methyl acrylate, 15 parts by mass of 2-hydroxyethyl acrylate, and 20 parts by mass of glycidyl methacrylate; weight average molecular weight: 800,000) 17 parts by mass (in terms of solid content, hereinafter, the same applies)

(b) Thermosetting component: mixed epoxy resin (mixture of 60 parts by mass of liquid bisphenol A type epoxy resin (epoxy equivalent: 180 to 200), 10 parts by mass of solid bisphenol A type epoxy resin (epoxy equivalent: 800 to 900), and 30 parts by mass of dicyclopentadiene type epoxy resin (epoxy equivalent: 274 to 286)) 17 parts by mass

(c) Curing agent: dicyanamide (ADEKA hardener 3636AS, manufactured by ADEKA CORPORATION) 0.3 parts by mass, and 2-phenyl-4,5-di(hydroxymethyl)imidazole (Curezol 2PHZ, manufactured by SHIKOKU CHEMICALS CORPORATION) 0.3 parts by mass

(d) Coloring agent: carbon black (#MA650, average particle diameter: 28 nm, manufactured by Mitsubishi Chemical Corporation) 2 parts by mass

(e) Silane coupling agent: y-glycidoxypropyltrimethoxysilane (KBM-403, methoxy equivalent: 12.7 mmol/g, molecular weight: 236.3, manufactured by Shin-Etsu Chemical Co., Ltd.) 0.4 parts by mass

(f) Filler: amorphous silica filler (average particle diameter: 3 μm) 63 parts by mass

A first release sheet (SP-PET381031, manufactured by LINTEC Corporation) obtained by forming a silicone-based release agent layer on one surface of a polyethylene terephthalate (PET) film having a thickness of 38 μm and a second release sheet (SP-PET381130, manufactured by LINTEC Corporation) obtained by forming a silicone-based release agent layer on one surface of a PET film having a thickness of 38 μm were prepared.

First, on the release surface of the first release sheet, the coating agent for a protective film-forming film described earlier was applied using a knife coater in such a manner that the thickness of the finally obtained protective film-forming film was 25 μm, and dried to form a protective film-forming film. Then, the release surface of the second release sheet was superimposed onto the protective film-forming film to paste the two together, thereby obtaining a laminate composed of the first release sheet, the protective film-forming film (thickness: 25 μm), and the second release sheet. The laminate was long, and was rolled up to form a roll body.

(2) Preparation of Second Laminate including Pressure Sensitive Adhesive Sheet

The following components (g) to (i) were mixed and diluted with methyl ethyl ketone so that the solid content concentration was 25% by mass, thereby preparing a coating agent for a pressure sensitive adhesive layer.

(g) Main adhesive agent: energy ray-curable acrylic copolymer (copolymer obtained by copolymerizing 80 parts by mass of 2-ethylhexyl acrylate and 20 parts by mass of 2-hydroxyethyl acrylate and then reacting 2-isocyanatoethyl methacrylate with the hydroxyl groups of 2-hydroxylethyl acrylate in an amount corresponding to 0.5 moles with respect to 1 mole of 2-hydroxylethyl acrylate, weight average molecular weight: 600,000) 100 parts by mass

(h) Epoxy resin: bisphenol A type epoxy resin (jER828, manufactured by Mitsubishi Chemical Corporation) 2.1 parts by mass

(i) Photopolymerization initiator: 1-hydroxy-cyclohexyl-phenyl-ketone (Irgacure 184, manufactured by BASF) 3.2 parts by mass

A release sheet (SP-PET381031, manufactured by LINTEC Corporation) obtained by forming a silicone-based release agent layer on one surface of a PET film having a thickness of 38 μm, and a polypropylene film serving as a base material (manufactured by Mitsubishi Plastics, Inc., thickness: 80 μm) were prepared.

First, on the release surface of the release sheet, the coating agent for a pressure sensitive adhesive layer described earlier was applied using a knife coater in such a manner that the thickness of the finally obtained pressure sensitive adhesive layer was 5 μm, and dried to form a pressure sensitive adhesive layer. Thereafter, the base material described above was adhered to the pressure sensitive adhesive layer, thereby obtaining a second laminate which was configured of the pressure sensitive adhesive sheet composed of the base material and the pressure sensitive adhesive layer, and the release sheet. The laminate was long. The pressure sensitive adhesive layer of the laminate was irradiated with ultraviolet rays from the release sheet side (illuminance: 140 mW/cm², light quantity: 510 mJ/cm²) to cure the pressure sensitive adhesive layer. Then, the laminate was rolled up to form a roll body.

(3) Preparation of a Third Laminate including a Pressure Sensitive Adhesive Layer 4 for Jigs

The following components (j) and (k) were mixed and diluted with toluene so that the solid content concentration was 15% by mass, thereby preparing a coating agent for a pressure sensitive adhesive layer.

(j) Main adhesive agent: Acrylic copolymer (copolymer obtained by copolymerizing 69.5 parts by mass of butyl acrylate, 30 parts by mass of methyl acrylate, and 0.5 parts by mass of 2-hydroxyethyl acrylate, weight average molecular weight: 500,000) 100 parts by mass

(k) Crosslinking agent: Trifunctional TDI-based isocyanate compound (BHS8515, manufactured by Toyokemu Co., Ltd.) 5 parts by mass

First and second release sheets (SP-PET381031, manufactured by LINTEC Corporation) obtained by forming a silicone-based release agent layer on one surface of a PET film having a thickness of 38 μm, and a polyvinyl chloride film serving as a core material (manufactured by Okamoto Industries, Inc., thickness: 50 μm) were prepared.

First, on the release surface of the first release sheet, the coating agent for a pressure sensitive adhesive layer described earlier was applied using a knife coater in such a manner that the thickness of the finally obtained pressure sensitive adhesive layer was 5 μm, and dried to form a first pressure sensitive adhesive layer. Thereafter, the core material described above was adhered to the first pressure sensitive adhesive layer, thereby obtaining a laminate A composed of the core material, the first pressure sensitive adhesive layer, and the first release sheet. The laminate A was long, and was rolled up to form a roll body.

Then, on the release surface of the second release sheet, the coating agent for a pressure sensitive adhesive layer described earlier was applied using a knife coater in such a manner that the thickness of the finally obtained pressure sensitive adhesive layer was 5 μm, and dried to form a second pressure sensitive adhesive layer. Thereafter, an exposed surface of the core material in the laminate A described above was adhered to the second pressure sensitive adhesive layer, thereby obtaining a third laminate composed of the first release sheet, the first pressure sensitive adhesive layer, the core material, the second pressure sensitive adhesive layer, and the second release sheet. The laminate was long, and was rolled up to form a roll body.

### (4) Preparation of Fourth Laminate

The second release sheet was peeled off from the first laminate obtained in the above section (1) to expose the protective film-forming film. On the other hand, the release sheet was peeled off from the second laminate obtained in the above section (2) to expose the pressure sensitive adhesive layer. The first laminate and the second laminate were pasted together so that the protective film-forming film described above was brought into contact with the pressure sensitive adhesive layer, thereby obtaining a fourth laminate formed by laminating the pressure sensitive adhesive sheet composed of the base material and the pressure sensitive adhesive layer, the protective film-forming film, and the first release sheet.

### (5) Preparation of Protective Film-Forming Composite Sheet

The second release sheet was peeled off from the third laminate obtained in the above section (3), and an inner peripheral edge of the pressure sensitive adhesive layer for jigs was subjected to a half-cutting process while leaving the first release sheet, thereby removing the inner circular portion. At this time, the diameter (d₁) of the inner peripheral edge of the pressure sensitive adhesive layer for jigs was set to 160 mm.

The first release sheet was peeled off from the fourth laminate obtained in the above section (4), and the exposed protective film-forming film and the pressure sensitive adhesive layer for jigs which was exposed in the third laminate were superimposed and pressure bonded. Thereafter, the outer peripheral edge of the protective film-forming composite sheet was subjected to a half-cutting process while leaving the first release sheet in the third laminate, thereby removing the outer portion. At this time, the diameter of the outer peripheral edge of the protective film-forming composite sheet was set to 205 mm.

In this manner, a protective film-forming composite sheet was obtained, which was configured of: the pressure sensitive adhesive sheet formed by laminating the pressure sensitive adhesive layer (thickness: 5 μm) on the base material; the protective film-forming film laminated on the pressure sensitive adhesive layer side of the pressure sensitive adhesive sheet; the circular, pressure sensitive adhesive layer for jigs (d₁: 160 mm) laminated on the peripheral edge portion on the opposite side of the pressure sensitive adhesive sheet in the protective film-forming film; and the release sheet laminated on the opposite side of the protective film-forming film in the pressure sensitive adhesive layer for jigs.

### Example 2

A protective film-forming composite sheet was produced in the same manner as in Example 1, with the exception that the diameter (d₁) of the inner peripheral edge of the circular, pressure sensitive adhesive layer for jigs was set to 170 mm.

### Example 3

A protective film-forming composite sheet was produced in the same manner as in Example 1, with the exceptions that the diameter (d₁) of the inner peripheral edge of the circular, pressure sensitive adhesive layer for jigs was set to 170 mm, the coating agent for a pressure sensitive adhesive layer was changed to one obtained by mixing the following components (l) and (m) and diluting with methyl ethyl ketone so that the solid content concentration was 25% by mass, and the pressure sensitive adhesive layer of the laminate was not irradiated with ultraviolet rays.

(l) Main adhesive agent: Acrylic copolymer (copolymer obtained by copolymerizing 59 parts by mass of butyl acrylate, 36 parts by mass of 2-ethylhexyl acrylate, and 5 parts by mass of 2-hydroxyethyl acrylate, weight average molecular weight: 700,000) 100 parts by mass

(m) Crosslinking agent: Trifunctional xylylene diisocyanate compound (D-110N, manufactured by Mitsui Takeda Chemicals, Inc.) 21.4 parts by mass

### Example 4

A protective film-forming composite sheet was produced in the same manner as in Example 3, with the exception that the coating agent for a pressure sensitive adhesive layer was changed to one obtained by mixing the following components (n) and (o) and diluting with methyl ethyl ketone so that the solid content concentration was 25% by mass.

(n) Main adhesive agent: Acrylic copolymer (copolymer obtained by copolymerizing 40 parts by mass of 2-ethylhexyl acrylate, 40 parts by mass of vinyl acetate, and 20 parts by mass of 2-hydroxyethyl acrylate, weight average molecular weight: 700,000) 100 parts by mass

(o) Crosslinking agent: Trifunctional xylylene diisocyanate compound (D-110N, manufactured by Mitsui Takeda Chemicals, Inc.) 40.1 parts by mass

### Example 5

A protective film-forming composite sheet was produced in the same manner as in Example 3, with the exception that the coating agent for a pressure sensitive adhesive layer was changed to one obtained by mixing the following components (p), (q) and (r) and diluting with methyl ethyl ketone so that the solid content concentration was 25% by mass.

(p) Main adhesive agent: Acrylic copolymer (copolymer obtained by copolymerizing 60 parts by mass of 2-ethylhexyl acrylate, 30 parts by mass of methyl methacrylate, and 10 parts by mass of 2-hydroxyethyl acrylate, weight average molecular weight: 500,000) 100 parts by mass

(q) Crosslinking agent: Trifunctional xylylene diisocyanate compound (D-110N, manufactured by Mitsui Takeda Chemicals, Inc.) 40.1 parts by mass

(r) Epoxy resin: bisphenol A type epoxy resin (jER828, manufactured by Mitsubishi Chemical Corporation) 15.6 parts by mass

### Comparative Example 1

A protective film-forming composite sheet was produced in the same manner as in Example 1, with the exception that the thickness of the pressure sensitive adhesive layer was set to 11 μm.

### Comparative Example 2

A protective film-forming composite sheet was produced in the same manner as in Example 1, with the exception that the base material alone of Example 1 was used in place of the second laminate in Example 1.

### Test Example 1

### Loosening Evaluation

The release sheets were peeled off from the protective film-forming composite sheets produced in Examples and Comparative Examples, and the resulting protective film-forming composite sheets were adhered to silicone wafers (#2,000 polished, outer peripheral edge diameter (d₂): 150 mm, thickness: 350 μm, mass: 14 g) and ring frames (made of stainless steel, with an inner diameter of 195 mm), as shown in FIG. 3. At this time, the above protective film-forming composite sheets were adhered so that the inner peripheral edge of the pressure sensitive adhesive layer for jigs, the inner peripheral edge of the ring frame, and the outer peripheral edge of the silicone wafer formed concentric circles. In that state, the protective film-forming film was cured by heating for 2 hours at 130° C., and then cooled to room temperature.

Then, the difference between the height of the lower end surface of the protective film-forming composite sheet located on the lower side of the ring frame and the height of the lower end surface of the protective film-forming composite sheet located on the lower side of the semiconductor wafer (sinking amount; mm) was measured, and this difference was evaluated as a degree of loosening. The evaluation criteria are as follows. The results are shown in Table 1.

A: Difference of less than 0.5 mm

B: Difference of 0.5 mm or more, but less than 2.0 mm

C: Difference of 2.0 mm or more

According to the above results, subsequent tests were not carried out for the protective film-forming composite sheet of Comparative Example 1 since the degree of loosening was large.

### Test Example 2

### Dicing Evaluation

The silicone wafer of the protective film-forming composite sheet with the wafer/ring frame after heating and cooling steps which was produced in Test Example 1 was diced into a chip size of 5 mm×5 mm, thereby obtaining a chip with a protective film. The number of flying chips and the presence of cutting chips during the dicing process was determined by visual observation and evaluated according to the following criteria. The results are shown in Table 1.

### [Evaluation of Chip Flying]

A: No chip flying was observed.

B: 1 to 4 cases of chip flying occurred.

C: 5 or more cases of chip flying occurred.

### [Evaluation of Cutting Chips]

A: Cutting chips were absent.

B: Cutting chips were generated.

### Test Example 3

### Pickup Evaluation

The chip with a protective film was picked up from the protective film-forming composite sheet which was subjected to a dicing process in Test Example 2. At this time, the protective film-forming composite sheet was thrusted using a needle from the base material side. Among the chips with a protective film that were obtained by picking up, the number of those in which chipping of the chip or separation of the protective film occurred (number of “no good” (NG) products) was counted, and the pickup was evaluated according to the following criteria. The results are shown in Table 1.

A: There was no chip in which chipping or protective film separation was observed.

B: There were one or two chips in which chipping or protective film separation was observed.

C: There were three or more chips in which chipping or protective film separation was observed.

### Test Example 4

### Pickup Force Evaluation

When carrying out the picking up process in the same manner as in Test Example 3, the force (N) required for the pickup was measured using a push-pull gauge (RX-1, manufactured by Aikoh Engineering Co., Ltd.). The average value of the measured values for 20 chips was defined as a pickup force and was evaluated by the following criteria. The results are shown in Table 1.

A: Pickup force of less than 3.0N

B: Pickup force of 3.0N or more, but less than 5.0N

C: Pickup force of 5.0N or more

### Test Example 5

### Measurement of Storage Elastic Modulus

The pressure sensitive adhesive used in Examples and Comparative Examples was applied on the release surface of the release sheet to form a pressure sensitive adhesive layer, and a release surface of a release sheet which was prepared separately was pressure bonded to the exposed pressure sensitive adhesive layer, thereby producing a pressure sensitive adhesive sheet composed of the release sheet, the pressure sensitive adhesive layer, and the release sheet. The release sheet was peeled off from the pressure sensitive adhesive sheet, and a plurality of pressure sensitive adhesive layers were laminated so that the thickness of the layers was 200 μm. A rectangular-shaped piece of 30 mm×4 mm (thickness: 200 μm) was punched out from the obtained laminate of the pressure sensitive adhesive layers, and this was used as a measurement sample. It should be noted that with respect to the measurement sample composed of the pressure sensitive adhesive of Example 1 (and Example 2 and Comparative Example 1), ultraviolet rays were irradiated to the pressure sensitive adhesive layer in the same manner as in Example 1 to cure the pressure sensitive adhesive.

The measurement sample described above was mounted to a dynamic viscoelasticity measuring device (RHEOVIBRON DDV-01FP, manufactured by Orientec Co., Ltd.) so that the measurement distance was 20 mm, and the storage elastic modulus (Pa) was measured under the conditions of a frequency of 11 Hz, a measurement temperature range from −50 to 150° C., and a temperature increase rate of 3° C./min. The storage elastic moduli at 130° C. obtained from the measurement results are shown in Table 1.

TABLE 1

| | | | | | | | Pickup evaluation | | | | Storage |
|---|---|---|---|---|---|---|---|---|---|---|---|
| | Loosening evaluation | | Dicing evaluation | | | | Number of | | Pickup force evaluation | | elastic |
| | Loosening | | Chip flying | | Cutting chips | | NG | | Pickup | | modulus |
| | (mm) | Evaluation | Number | Evaluation | Presence | Evaluation | products | Evaluation | force (N) | Evaluation | (Pa) |
| Ex. 1 | 0.0 | A | 0 | A | Absent | A | 0 | A | 2.0 | A | 1.8 × 10⁷ |
| Ex. 2 | 0.2 | A | 0 | A | Absent | A | 0 | A | 2.0 | A | 1.8 × 10⁷ |
| Ex. 3 | 0.0 | A | 0 | A | Absent | A | 0 | A | 2.2 | A | 8.6 × 10⁵ |
| Ex. 4 | 0.2 | A | 0 | A | Absent | A | 1 | B | 4.5 | B | 8.7 × 10⁵ |
| Ex. 5 | 0.0 | A | 0 | A | Absent | A | 0 | A | 2.9 | A | 3.3 × 10⁵ |
| Comp. Ex. 1 | 2.5 | C | — | — | — | — | — | — | — | — | 1.8 × 10⁷ |
| Comp. Ex. 2 | 0.0 | A | 0 | A | Absent | A | 5 | C | 9.0 | C | — |

As can be seen from Table 1, with respect to the protective film-forming composite sheets produced in Examples, loosening was hardly observed in the heating and cooling steps, and it was also possible to carry out the dicing and picking up processes in a favorable manner.

### INDUSTRIAL APPLICABILITY

The protective film-forming composite sheet according to the present invention is suitably used for producing a chip with a protective film from a semiconductor wafer.

### REFERENCE SIGNS LIST

1, 1A: Protective film-forming composite sheet;

2: Pressure sensitive adhesive sheet;

21: Base material;

22: Pressure sensitive adhesive layer;

3: Protective film-forming film;

4: Pressure sensitive adhesive layer for jigs;

5: Semiconductor wafer;

6: Ring frame

1. A composite sheet for forming a protective film, the composite sheet comprising:
a pressure sensitive adhesive sheet obtained by laminating a pressure sensitive adhesive layer on one surface of a base material;
a protective film-forming film laminated on said pressure sensitive adhesive layer side of said pressure sensitive adhesive sheet; and
a pressure sensitive adhesive layer for jigs which is laminated on a peripheral edge portion on a side opposite to said pressure sensitive adhesive sheet side of said protective film-forming film,
wherein a thickness of said pressure sensitive adhesive layer of said pressure sensitive adhesive sheet is from 1 to 8 μm.

2. A composite sheet for forming a protective film, the composite sheet comprising:
a pressure sensitive adhesive sheet obtained by laminating a pressure sensitive adhesive layer on one surface of a base material;
a protective film-forming film laminated on a central portion on said pressure sensitive adhesive layer side of said pressure sensitive adhesive sheet; and
a pressure sensitive adhesive layer for jigs which is laminated on a peripheral edge portion on said pressure sensitive adhesive layer side of said pressure sensitive adhesive sheet,
wherein a thickness of said pressure sensitive adhesive layer of said pressure sensitive adhesive sheet is from 1 to 8 μm.

3. The composite sheet for forming a protective film according to claim 1,
wherein said base material is a polypropylene film, or a laminated film obtained by combining a polypropylene film with another type of film.

4. The composite sheet for forming a protective film according to claim 1,
wherein said pressure sensitive adhesive layer for jigs is formed so as to have a circular shape, and so that, when said protection-film forming film is adhered to a workpiece, a gap in the plane direction between the main outer peripheral edge of said workpiece and the inner peripheral edge of said pressure sensitive adhesive layer for jigs is less than 10 mm.

5. The composite sheet for forming a protective film according to claim 1,
wherein a storage elastic modulus at 130° C. of a pressure sensitive adhesive constituting said pressure sensitive adhesive layer is from 1.0×10⁵ to 8.0×10⁶ Pa.

6. The composite sheet for forming a protective film according to claim 1,
wherein said workpiece is a semiconductor wafer, and
said protective film-forming film is a layer for forming a protective film on said semiconductor wafer or a semiconductor chip obtained by dicing said semiconductor wafer.

7. The composite sheet for forming a protective film according to claim 2, wherein said base material is a polypropylene film, or a laminated film obtained by combining a polypropylene film with another type of film.

8. The composite sheet for forming a protective film according to claim 2, wherein said pressure sensitive adhesive layer for jigs is formed so as to have a circular shape, and so that, when said protection-film forming film is adhered to a workpiece, a gap in the plane direction between the main outer peripheral edge of said workpiece and the inner peripheral edge of said pressure sensitive adhesive layer for jigs is less than 10 mm.

9. The composite sheet for forming a protective film according to claim 2, wherein a storage elastic modulus at 130° C. of a pressure sensitive adhesive constituting said pressure sensitive adhesive layer is from 1.0×105 to 8.0×106 Pa.

10. The composite sheet for forming a protective film according to claim 2, wherein said workpiece is a semiconductor wafer, and
said protective film-forming film is a layer for forming a protective film on said semiconductor wafer or a semiconductor chip obtained by dicing said semiconductor wafer.
